(19) United States
(12) Patent Application Publication
(10) Pub. No.: US 2009/0190371 A1
(43) Pub. Date: Jul. 30, 2009

(54) MONOLITHIC ILLUMINATION DEVICE

(75) Inventors: Thomas V. Root, Beverly, MA (US); Robert J. Krupa, Leominster, MA (US)

Correspondence Address: PROSKAUER ROSE LLP, ONE INTERNATIONAL PLACE, BOSTON, MA, 02110, US

(73) Assignee: Optim, Inc., Sturbridge, MA (US)

(21) Appl. No.: 12/360,027

(22) Filed: Jan. 26, 2009

Related U.S. Application Data
(60) Provisional application No. 61/023,253, filed on Jan. 24, 2008.

(51) Int. Cl. G02B 6/04; F21V 29/00; F21L 4/00; F21V 9/16; H01L 21/02

(52) U.S. Cl. 362/554; 362/294; 362/157; 362/580; 362/249.02; 362/84; 438/31; 257/E21.002

(57) ABSTRACT

A monolithic light engine includes a heat sink, a semiconductor light source (e.g., a light emitting diode, a plurality of semiconductor light sources), and a light conduit. The semiconductor light source includes a light-emitting top surface and a back surface thermally coupled to the heat sink. In some embodiments, the monolithic light engine includes a wavelength converter. The wavelength converter converts a first wavelength or range of wavelengths emitted from the light-emitting surface to a second wavelength or range of wavelength light. The light of the second wavelength range enters the light conduit and is transmitted along the length of the light conduit to illuminate an object placed at some distance away from the light source. The heat sink, light source, and the light conduit are mechanically, rigidly coupled (e.g., via one or more mechanical connectors) so as to form a monolithic light engine.

### RELATED APPLICATIONS

This application relates to and claims the benefit and priority of provisional application entitled “Monolithic Illumination Device,” U.S. Patent Application No. 61/023,253, filed on Jan. 24, 2008, the disclosure of which is hereby incorporated herein by reference in its entirety.

### FIELD OF THE TECHNOLOGY

This technology relates, in general, to an illumination device that includes a light-emitting semiconductor element (e.g., light emitting diode, laser diode, vertical cavity surface emitting laser), a wavelength converter layer (e.g., a phosphor, fluorophor), and a light conduit in a single, monolithic package, including a mechanical connector.

### BACKGROUND OF THE TECHNOLOGY

Light sources for illumination devices are generally of two types: incandescent filament lamps and arc lamps. Incandescent lamps produce light by passing current through a tungsten filament, causing it to radiate light in proportion to its blackbody color temperature. The hotter the filament, the higher its color temperature and the more nearly it approaches daylight with a color temperature of approximately 5500K. Tungsten filament lamps range in color temperature from approximately 2400-3400K. Because of the low color temperature, objects illuminated by a tungsten filament light source appear slightly yellow due to the low output of blue light from these sources. Arc lamps produce light by creating a plasma between two electrodes within the sealed bulb. White light from these lamps can be produced by choosing the appropriate fill gas (usually Xe) and pressure (usually several atmospheres). Color temperature of common arc lamps is approximately 4000-6000K. Both types of lamps, filament and arc, are very inefficient in converting electrical power to light, and consequently produce large amounts of heat, which needs to be dissipated. In addition, the heat generated by these lamps contributes to a shortened useful life, thereby requiring frequent maintenance and replacement of the light source in an illumination device.

There have been numerous attempts to utilize light emitting diodes (LEDs) coupled to fiber optic light guides as light sources for endoscopy, dentistry, and for remote illumination of objects (as with a flashlight). In general, a LED includes a dome lens or a flat window (e.g., a substantially flat light transmitting plate, a substantially flat light transmitting encapsulant), and a LED semiconductor chip positioned underneath the dome lens or window. Most of these prior attempts employ numerous low power (<1 W electrical power consumption, typically operating below 100 mW) LEDs for remote illumination. Multiple LEDs are necessary because the light output from a single, low power LED is very low and there is poor coupling of light emitted by the LED(s) into the optical fiber. Even with external optical components (e.g., mirrors, lenses, reflectors, etc.) the optical coupling and light transmission with low power LEDs is ineffective for most lighting uses.

Researchers have also tried to couple high power LEDs with light conduits (e.g., optic light guides) to form various illumination devices, such as, for example, endoscopes. To couple the high powered LED to a light conduit some researchers have used reflectors or optics between the LED and light conduit. Others have tried to connect the dome lens that encapsulates at least the top portion of an underlying LED semiconductor chip to a light conduit. Still others have created an opening or aperture within the dome lens and positioned the light conduit within a silicone-based gel sandwiched between the dome lens and the light emitting surface of the LED semiconductor chip. In each of these embodiments, light losses due to inefficient coupling has limited the amount of light transmitted from the light source through the light conduit. In addition, a non-rigid, non-mechanical connection between the light source and the light conduit prevents interchangeability of an illumination device within a system without the need for a complex alignment procedure between the light source and the light conduit.

### SUMMARY OF THE TECHNOLOGY

Applicants have discovered that an illumination device that includes a monolithic package of a light source, a heat sink, a wavelength converter, and a light conduit provides a greater amount of light transmittance than conventional devices. That is, an illumination device that includes a single, monolithic package with a mechanical connector (i.e. a mechanical connection such as a screw or thermoset mechanical connection is utilized alone or in addition to any optical gel) produces more light at an illumination site than conventional illumination devices including similar powered light sources. As a result, the monolithic illumination device can be smaller than conventional light illumination devices, while still providing a brighter illumination.

Illumination devices as used herein refers to any device that illuminates or lights an object located remotely from the light source. Examples of illumination device include, but are not limited to, industrial endoscopes, medical endoscopes, microscopes, machine vision (e.g., viewing and/or imaging products employed to image a manufacturing process, to inspect and/or view a welding site, etc.), flashlights, display-case lighting, home lighting including novelty lighting such as spot lighting and shower lighting, dashboard and interior lighting for automotive, aircraft, and seacraft industries, and instrument control display lighting.

In general, one aspect of the technology is directed to a monolithic light engine. The monolithic light engine includes a heat sink. In this first aspect, the monolithic light engine also includes a light emitting diode light source including a substantially planar light-emitting top surface and a back surface thermally coupled to the heat sink. The monolithic light engine further includes a light conduit including a light receiving end disposed proximate to the substantially planar light-emitting top surface of the light source. The monolithic light engine also includes one or more mechanical connectors to rigidly couple the heat sink, the light source, and the light conduit together to form the monolithic light engine.

Embodiments of this aspect of the technology can include one or more of the following features. The light emitting diode light source can be battery powered. The light conduit can include a fiber bundle, a single fiber, a rod, a taper, and/or a liquid light guide. The light conduit can be a glass light conduit, a plastic light conduit, a clad rod, a clad fiber, a clad taper, a reflective-coated rod, a reflective-coated fiber, and/or a reflective-coated taper. The light conduit can be a taper including a geometric shape. The geometric shape can be a circle, a square, or a hexagon.

In other embodiments, the light conduit is a taper, wherein the light receiving end includes a first geometric shape and a light transmitting end of the light conduit includes a second geometric shape. The light emitting diode light source can include a single light emitting diode. The light emitting diode light source can include a plurality of light emitting diodes. In some embodiments, at least two of the plurality of light emitting diodes can emit a different color.

In some embodiments, the heat sink comprises a passive heat sink. The heat sink can include an active heat sink. The monolithic light engine can include a driver to control light emission from the light emitting diode light source. The substantially planar light-emitting top surface and the light receiving end of the light conduit can be selected to have substantially similar surface areas. The substantially planar light-emitting top surface of the light source can be free of an encapsulant. In other embodiments, a light transmitting plate can protect the substantially planar light-emitting top surface of the light source.

The monolithic light engine can include a wavelength converter disposed between the substantially planar light-emitting top surface of the light source and the light receiving end of the light conduit. The wavelength converter can include an adhesive or a gel with particles disposed therein, the particles being selected from the group consisting of phosphorescent particles, fluorescent particles, and combinations thereof. In some embodiments, the adhesive with the particles disposed therein mechanically couples the light source to the light conduit. The wavelength converter can include a ceramic including one or more phosphorescent materials and/or one or more fluorescent materials disposed therein. The ceramic can be a solid disk disposed between the substantially planar light-emitting top surface of the light source and the light receiving end of the light conduit. The wavelength converter can include at least one of a phosphor or a fluorophor.

A second aspect of the technology is also directed to a monolithic light engine. The monolithic light engine includes a heat sink. The monolithic light engine also includes a semiconductor light source including a light-emitting top surface and a back surface thermally coupled to the heat sink. The monolithic light engine also includes a wavelength converter for converting a first wavelength range emitted from the light-emitting surface to a second wavelength range. The monolithic light engine also includes a light conduit including a light receiving end disposed proximate to the wavelength converter. The heat sink, the semiconductor light source, the wavelength converter, and the light conduit are mechanically, rigidly coupled so as to form a monolithic light engine.

Embodiments of this aspect of the technology can include one or more of the following features. The semiconductor light source, the wavelength converter, and the light conduit can be mechanically coupled by a sleeve. The semiconductor light source, the wavelength converter, and the light conduit can be mechanically coupled by a solid-phase adhesive. The heat sink can include a passive heat sink. The heat sink can include an active heat sink. The semiconductor light source can be battery powered.

In some embodiments, the wavelength converter includes an adhesive or a gel with particles disposed therein, the particles being selected from the group consisting of phosphorescent particles, fluorescent particles and combinations thereof. The adhesive with the particles disposed therein can mechanically couple the light source to the light conduit. The wavelength converter can include a ceramic including one or more phosphorescent materials and/or one or more fluorescent materials disposed therein. The ceramic can be a solid disk disposed between the light-emitting top surface of the light source and the light receiving end of the light conduit. In other embodiments, the wavelength converter includes at least one of a phosphor or a fluorophor.

The light conduit can include a fiber bundle, a single fiber, a rod, a taper, and/or a liquid light guide. The light conduit can be a glass light conduit and/or a plastic light conduit. The light conduit can be a clad rod, a clad fiber, or a clad taper. The light conduit can be a reflective-coated rod, a reflective-coated fiber, or a reflective-coated taper. The light conduit can be a taper comprising a geometric shape. The geometric shape can be a circle, a square, or a hexagon. The light conduit can be a taper, wherein the light receiving end comprises a first geometric shape and the light transmitting end comprises a second geometric shape.

In some embodiments, the semiconductor light source includes a single light emitting device. The semiconductor light source can include a plurality of light emitting devices. The monolithic light engine can include a driver to control light emission from the semiconductor light source. The light-emitting top surface of the semiconductor light source and the light receiving end of the light conduit can be selected to have substantially matching surface areas.

In general, a third aspect of the technology is directed to a monolithic light engine. The monolithic light engine includes a heat sink. The monolithic light engine also includes a plurality of semiconductor light sources, each source including a substantially planar light-emitting top surface and a back surface thermally coupled to the heat sink. The monolithic light engine also includes a light conduit including a light receiving end disposed proximate to the substantially planar light- emitting top surface of each of the plurality of semiconductor light sources. The monolithic light engine also includes one or more mechanical connectors to rigidly couple the heat sink, the plurality of semiconductor light sources, and the light conduit together to form the monolithic light engine.

Embodiments of this aspect of the technology can include one or more of the following features. The light conduit can include a fiber bundle, a single fiber, a rod, a taper, and/or a liquid light guide. The light conduit can be a glass light conduit and/or a plastic light conduit. In some embodiments, at least two of the plurality of semiconductor light sources can emit a different color. The heat sink can include a passive heat sink. The heat sink can include an active heat sink. The monolithic light engine can include a driver to control light emission from the plurality of semiconductor light sources.

In some embodiments, a total emitting area is defined by a sum of each of the substantially planar light-emitting top surfaces of the plurality of semiconductor light sources, the total emitting area and the light receiving end of the light conduit are selected to have substantially similar surface areas.

The monolithic light engine can include a wavelength converter disposed between the substantially planar light-emitting top surface of at least one within the plurality of semiconductor light sources and the light receiving end of the light conduit. The wavelength converter can include an adhesive or a gel with particles disposed therein, the particles being selected from the group consisting of phosphorescent particles, fluorescent particles, and combinations thereof. In other embodiments, the adhesive with the particles disposed therein mechanically couples the plurality of semiconductor light sources to the light conduit. The wavelength converter can include a ceramic including one or more phosphorescent materials and/or one or more fluorescent materials disposed therein. The ceramic can be a solid disk. The wavelength converter can include at least one of a phosphor or a fluorophor.

In general, one aspect of the technology is directed to a method of manufacturing an illumination device. The method includes providing a semiconductor device including a substantially planar light-emitting surface. The method also includes providing a light conduit including a light receiving end and a light transmitting end. The method also includes positioning a wavelength converter between the light receiving end of the light conduit and the substantially planar light-emitting surface. The method further includes aligning the light receiving end of the light conduit to the substantially planar light-emitting surface. The method also includes securing the light conduit to the semiconductor device to form a rigid connection.

Embodiments of this aspect of the technology can include one or more of the following features. Positioning the wavelength converter can include depositing a film including at least one of a phosphorescent material or fluorescent material on either the light receiving end of the light conduit or on the substantially planar light-emitting surface of the semiconductor device. Positioning the wavelength convert can include positioning a phosphor or fluorophor layer between the semiconductor device and the light conduit.

In some embodiments, positioning the wavelength converter includes positioning an element formed of a medium including one or more phosphor elements and/or one or more fluorophor elements disposed therein between the light receiving end of the light conduit and the substantially planar light-emitting surface of the semiconductor device. The light receiving end of the light conduit and the substantially planar light-emitting surface of the semiconductor device can be secured by a solid-phase adhesive.

In other embodiments, the light receiving end of the light conduit and the substantially planar light-emitting surface of the semiconductor device are attached by a sleeve. Providing the semiconductor device can including the substantially planar light-emitting surface can include providing a light emitting diode with a flat package. Providing the semiconductor device including the substantially planar light-emitting surface can include providing a light emitting diode including an encapsulant and planarizing the encapsulant to form the substantially planar light-emitting surface.

In general, one aspect of the technology is directed to a method of manufacturing an illumination device. The method includes providing a plurality of semiconductor light sources, each source including a substantially planar light-emitting top surface. The method also includes providing a light conduit including a light receiving end disposed proximate to the substantially planar light-emitting top surface of each of the plurality of semiconductor light sources and a light transmitting end. The method further includes positioning a wavelength converter between the light receiving end of the light conduit and the substantially planar light-emitting surface of at least one of the plurality of semiconductor light sources. The method also includes aligning the light receiving end of the light conduit to the substantially planar light-emitting surface of each of the plurality of semiconductor light sources. The method also includes securing the light conduit to the plurality of semiconductor devices to form a rigid connection.

### BRIEF DESCRIPTION OF THE DRAWINGS

In the drawings, like reference characters generally refer to the same parts throughout the different views. Also, the drawings are not necessarily to scale, emphasis instead being placed upon illustrating the principles of the disclosure.

FIG. 1 is a schematic of an embodiment of a monolithic light engine in accordance with an embodiment of the technology;

FIG. 2 is a schematic of an embodiment of a monolithic light engine in accordance with a second embodiment of the technology;

FIG. 3A is a schematic illustrating an exploded view and a secured view of a mechanical connector with light source and light conduit; and

FIG. 3B is a schematic illustrating an exploded view and a secured view of a mechanical connector with light source and light conduit that does not extend beyond the sleeve.

### DESCRIPTION OF THE TECHNOLOGY

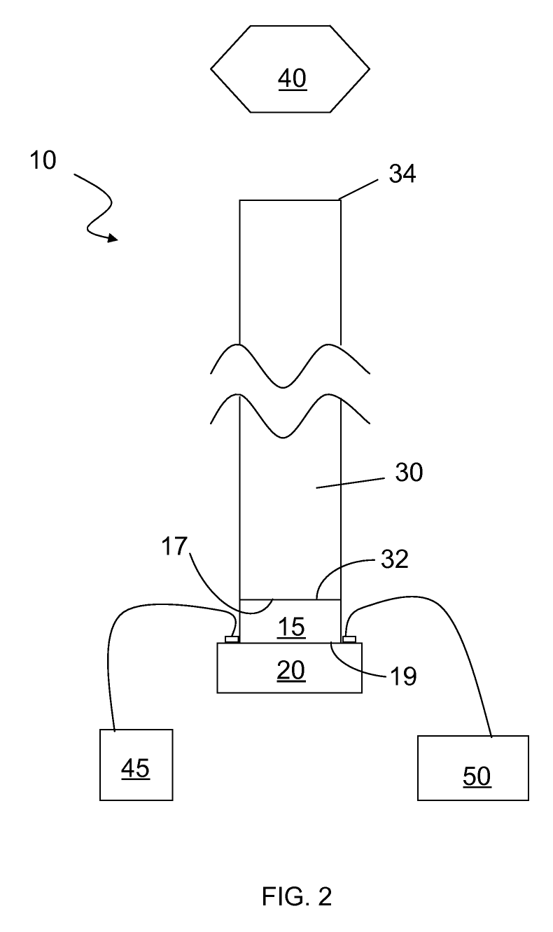

An illumination device including a monolithic light engine 10 includes a light source 15, a heat sink 20 thermally coupled to the light source 15, a wavelength converter 25, and a light conduit 30. In a second embodiment described in FIG. 2, the wavelength converter 25 is not used so as to be able to emit a single light color for single color applications (e.g., when UV or blue light is needed from an illumination device, or if several different colored light sources are employed to create the desired colored output). The light source 15 has at least one light emitting surface 17 and a back surface 19. In general, the light emitting surface 17 is a substantially planar surface. The back surface 19 is thermally connected to the heat sink 20, such that heat generated by the light source during operation is thermally removed from the light source 15 to the heat sink 20. Disposed proximate to the light emitting surface 17 of the light source 15 is a light receiving end 32 of the light conduit 30. Sandwiched between the light-receiving end 32 and the light source 15 is the wavelength converter 25, which transforms or converts light of a first wavelength region to a second wavelength region. In general, the wavelength converter 25 can be used to convert a particular color or wavelength or wavelengths of light (such as, for example, blue light) into a different wavelength of light (e.g., from blue light to orange light). The wavelength converter 25 can be used to shift a wavelength to a higher wavelength with a lower energy (e.g., blue light to orange light, blue light to infra red light, etc.) In addition, the wavelength converter 25 can be used to filter out a specific wavelength region of light determined to be undesirable to the illumination device operator. The wavelength converter 25 can also convert from one wavelength to a range of wavelengths (e.g., from blue light to white light). In some examples, the wavelength converter 25 is disposed on the light emitting surface 17, between the light emitting surface 17 and the light receiving end 32 of light conduit 30, and/or on the light receiving end 32 of light conduit 30. In some examples (see FIG. 2), wavelength converter 25 is omitted from the illumination device for specific uses of a single color light (e.g., for an illumination device application requiring green or UV light). In some examples where the wavelength converter 25 is omitted, light source 15 is a single wavelength light source.

The light generated from the light source 15 is emitted through the light emitting surface 17 and passes through the wavelength converter 25 and into the light receiving end 32 of the light conduit 30. The light is then transmitted through the light conduit 30 and exits the light conduit 30 at a light transmitting end 34 to illuminate a remote object 40. The heat sink 20, light source 15, wavelength converter 25, and light conduit 30 are mechanically coupled together so that they are a single unit (i.e., monolithic device) that can be replaced or positioned without the need for aligning individual components. In some embodiments, the monolithic light engine 10 can be included within a clip or other attachment device which can then be placed or positioned as a user desires (e.g., at a proximal (i.e., light transmitting end) of an endoscope, at a work station, as a portable flashlight). In other embodiments, the monolithic light engine 10 is included within a device (e.g., endoscope, automotive display unit) and can be removed or replaced by opening or gaining access to the interior of the device. Alternatively, the light engine 10 can be external to the device and coupled to the device with a quick connect connector. The monolithic light engine 10 does not use liquid or gelatinous phase materials to hold individual components (e.g., light source, light conduit) together, but rather uses solid-phase materials to mechanically couple the components. However, in some embodiments, optical gels and/or epoxies can be used in addition to one or more mechanical connectors to aid in optical transmission of light from the light source 15 to the light conduit 30. In such embodiments, the mechanical components (e.g., connectors) are still used to couple and/or hold the components, whereas the optical gels and/or epoxies are utilized to increase the optical transmission of the components (e.g., for optical coupling between the components).

The monolithic light engine 10 can also include circuitry 45 to drive the light output from the light source 15. Specifically, the circuitry 45 is electrically connected to the light source 15 and supplies an algorithm to control one of: power step increases or decreases during warm-up or cool-down stages, the power supplied, or the light emitted over the operational life of the light source 15. The circuitry 45 can be built into the monolithic light engine 10, or it can be a detachable component that can be secured within a housing and attached to the light engine 10 prior to use.

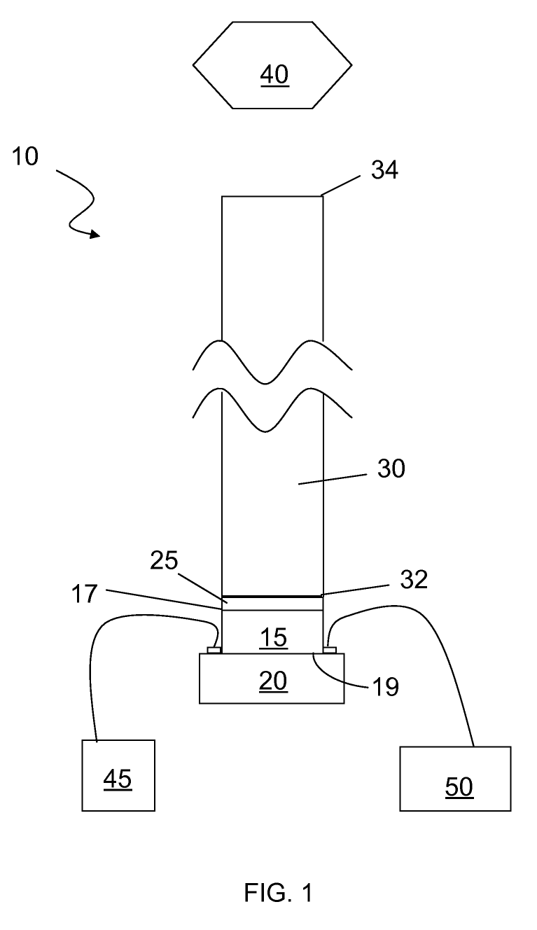

Another optional element of this embodiment of the light engine 10 shown in FIG. 1 is a battery 50. The battery 50 powers the light source 15 directly, or through the circuitry 45. The battery 50 can be incorporated into the light engine 10 or, alternatively, the battery 50 can be attached to a housing and connected to the light engine 10 prior to use. The battery 50 can be rechargeable, such as a rechargeable lithium ion battery. In general, the size and power of the battery 50 is selected to provide adequate lifetime for the application. In some examples, the size and power of the battery 50 is selected to provide thirty to forty-five minutes of light output at full power. In some examples, such as nasopharyngology, the size and power of battery 50 is selected to provide about ten to fifteen minutes of useful light output from the light engine 10. The battery could also be replaced by another power source, such as a DC or AC power source that is electrically connected directly to the light source 15 or through the electronic circuitry 45 before reaching the light source 15.

### Light Sources

In general, the light source 15 for the monolithic light engine 10 is a semiconductor light source (e.g., a high power LED semiconductor chip, vertical-cavity surface-emitting laser (VCSEL)). In general, the semiconductor light source has a substantially planar light emitting surface. For example, in embodiments which feature a LED, the light emitting diode chip includes a substantially flat light emitting surface (e.g., a flat semiconductor chip surface, a flat transparent window covering the chip surface, a flat light transmitting encapsulant). The LED does not have a dome or convex shaped lens attached over the LED when positioned within the light engine 10 (e.g., the light emitting surface of the LED chip is exposed, the LED package is free of convex/concave optical components).

The light source 10, in some embodiments, can be formed of a single light emitting device. For example, the light emitting device can be a single LED chip. In other embodiments, light source 10 includes two or more (i.e., multiple) light emitting devices. For example, the light source 10 can include two or more LED chips to form the light source. When two or more LED chips are utilized, the light emitting surface 17 of the light source is formed of the light emitting surfaces of each LED chip. That is, the size or light emitting area of the light source is calculated by including the surface areas of each light emitting surface of each LED chip forming the light source 15. The two or more LED chips can emit the same wavelength range of light (i.e. emit the same color of light or same type of radiation) or the LED chips can emit different wavelength ranges. In certain embodiments, the light source 10 emits wavelengths in the UV range, the infrared range, or in other wavelength ranges. The two or more LED chips can be disposed in separate packages, or alternatively, a device such as Cree MC-E (Cree, Inc. 4600 Silicon Drive, Durham, N.H.) which includes multiple chips disposed within one package can be utilized.

In some embodiments light source 10 is a LED having a flat package design. That is, the LED includes a light transmitting plate (i.e., window, light transmitting encapsulant) above the LED chip. The window can be a plastic or glass plate. In other embodiments, the window can be an encapsulant, such as an epoxy or silicone adhesive, that is used to cover the light emitting surface and/or wavelength converter without being an actual window placed on the package. For example, the package can be filled with the encapsulant or adhesive and intentionally left flat, or a curved encapsulant can be cut, ground and/or polished to be a flat surface, or the curved or thick encapsulant can be removed, exposing the light emitting surface (or phosphor) of the LED. The window can be, for example, a plate or some other flat, relatively thin body of uniform thickness.

Examples of some LED chips that can be used as light sources include the Luxeon III Model LXH:-LW3C or the Luxeon K2 Model LXK2-PWC4-0200, both from Philips Lumileds Lighting Company of San Jose, Calif.; the Microsemi, UPW3LEDxx product from Microsemi, of Watertown, Mass.; the Luminus CBT-90 or CBM-360, both from Luminus Devices of Billerica, Mass.; Cree MC-E from Cree Inc. of Durham, N.H. The Luxeon III, the Luxeon K2, and the Cree MC-E LEDs are packaged with a dome lens and gel covering the one or more LED chips. To utilize the Luxeon III, Luxeon K2, and Cree MC-E as light sources in the light engine 10, at least some portion, if not all, of the dome and optical gel is removed to expose and obtain a substantially flat light emitting surface.

### Light Conduits

The light conduit 30 transmits light from the light source 15 to illuminate a remote object 40 located at some distance away from the light source. The light receiving end 32 of the light conduit is mechanically coupled to the wavelength converter 25 such that it is located proximate to the light source 15. In addition, the light receiving end 32 of the light conduit can be sized to substantially match or approximate the light emitting surface 17 of the light source, so that efficient coupling between the light source 15 and the light conduit 30 is achieved. That is, the emitting surface area of the light emitting surface 17 and the light receiving area of the light receiving end 32 are similarly sized.

In certain embodiments, the light conduit 30 is formed from a single optical fiber. In other embodiments the light conduit 30 is formed from a fiber bundle. Other examples of light conduits include: glass or plastic rods, glass or plastic tapers, liquid light guides, glass fibers, and plastic fibers. It should be understood for purposes of this specification that the terms fiber and rod can be used interchangeably. Light conduits can also be formed of a hollow tube or device having any cross-sectional shape. In general, the hollow tube has a light reflective coating within the interior of the hollow tube or device. In some examples, the light conduits are clad or coated with a reflective coating (e.g., gold, silver, aluminum, etc.). The light conduits can have different geometric cross-sectional shapes. For example, the light conduit can be a circular or round light conduit, a square light conduit, a hexagonal light conduit, or a light conduit with any other geometric shape. The light conduits can have different geometric shapes on the light receiving end and the light transmitting end. For example, the light receiving end can be round and the light transmitting end can be square, the light receiving end can be round and the light transmitting end can be rectangular (e.g., a high aspect ratio shape), etc. The light conduits can be hollow (e.g., a round or square light conduit with the interior coated with a reflective material).

The light conduit can include multiple distinct parts. For example the light conduit can include a rod or a taper attached to a fiber to form the light conduit. As a result, the numerical aperture of the light conduit 30 can be modified so as to receive the maximum amount of light from the light emitting surface 17.

In certain embodiments, the wavelength converter 25 is incorporated into the light receiving end 32 of the light conduit 30. For example, in one embodiment, the wavelength converter 25 can be deposited (e.g., vapor deposited, adhered) on the light receiving end 32 of the conduit prior to its attachment to the light source 15. In another embodiment, the wavelength converter 25 can be combined with a solid-phase adhesive (e.g., an epoxy that cures to a solid-phase) or a semi-solid gel and positioned at the light receiving end of the fiber or fiber bundle.

### Wavelength Converters

While the wavelength converter 25 can be deposited or positioned at the light receiving end 32 of the light conduit 30, the wavelength converter 25 can also be disposed on or proximate to the substantially flat light emitting surface 17 of the light source. The wavelength converter can include solid wavelength conversion particles (e.g., phosphors and/or fluorophors) disposed within a medium such as an adhesive, an index matching gel, a slurry, or an epoxy. A combination of a number of different phosphors and/or fluorophors can be used in combination. Alternatively, a single type of phosphor or fluorophor can be utilized. In some embodiments, the wavelength converter comprises a film of phosphors and/or flurophors. For example, a layer of material having light wavelength conversion properties (e.g., phosphor, fluorophor) can be vapor deposited onto the light emitting surface 17 of the LED. In other embodiments, the wavelength converter is a solid disk or a semi-solid, gelatinous medium (e.g., an epoxy) disposed between the light emitting surface 17 and the light receiving end 32 of the light conduit 30. In other embodiments, the wavelength converter 25 can be disposed within a transparent, substantially planar window covering the light emitting surface 17 of the LED. In some embodiments, the medium is a transparent medium. In another embodiment, the wavelength converter 25 includes a layer of a solid material sandwiched between the light source 15 and the light conduit 30. The solid wavelength converter 25 can be, for example, a crystal, a glass, or a ceramic material.

Examples of wavelength converters 25 include fluorophors and phosphors, which convert lower light wavelengths (e.g., blue light, UV light) into higher wavelengths or a broad band of wavelengths such as white light. For example, wavelength converter 25 can include one or more phosphor elements and/or one or more flurophor elements. Other wavelength converters 25 can filter out non-desired colors. For example, a possible wavelength converter can filter out blue light if so desired. Some wavelength converters 25 can convert one wavelength into another narrow band wavelength. For example, blue light can be converted to green light, red light can be converted to near-infra red light, etc.

In one embodiment of a monolithic light engine, no wavelength converter is utilized. FIG. 2 shows a monolithic light engine 10 for an illumination device that includes a light source 15, a heat sink 20 thermally coupled to the light source 15, and a light conduit 30. The light source 15 includes light emitting surface 17 and a back surface 19. The back surface 19 is thermally connected to the heat sink 20, such that heat generated by the light source during operation is thermally removed from the light source 15 to the heat sink 20. Disposed proximate to the light emitting surface 17 of the light source 15 is a light receiving end 32 of the light conduit 30. The light transmitting end 34 of the light conduit 30 illuminates a remote object 40. The battery 50 powers the light source 15 directly, or through the circuitry 45. Unlike the embodiment shown in FIG. 1, there is no wavelength converter between the light-receiving end 32 and the light source 15.

Wavelength converters can be omitted for monolithic light engines that produce a single color light. For example, in microscopy applications, a green light emitting LED chip can be used in combination with a light conduit and a mechanical connector to direct green light to the light transmitting end of the light conduit (i.e., no change in wavelength is desired). The light receiving end of the light conduit in this embodiment is substantially matched in size and shape of the substantially flat light emitting surface so that light can be effectively communicated from the light source to the light conduit.

### RGB Applications

In some embodiments, red, green, blue (RGB) LED semiconductor chips are utilized to create white light. Specifically, a plurality of LED chips (in which one or more chips emits red light, one or more chips emits green light, and one or more chips emits blue light, or other color combinations depending upon the application) are aligned with the light receiving end of the light conduit and are secured to form a monolithic light engine. In this embodiment, driver (circuitry) can be utilized to control the intensity of each of the red, green and blue LEDs to form a desired spectral output.

### Heat Sinks

The heat sink 20 of the monolithic light engine 10 removes heat from the light source 15 so as to preserve the useful lifetime of the light source and light engine 10. Excessive heat not only deteriorates the useful lifetime of the solid state light source, but also can decrease the light flux or intensity from a LED chip. For example, there is a decrease in light output as the temperature of the LED is increased.

There are many different types of possible heat sinks 20. For example, many LED light sources are attached to an aluminum-based printed circuit board. The aluminum-based printed circuit board is in direct contact with the back surface 19 of the light source 15 and as a result, the light source 15 and the heat sink 20 are in direct thermal contact with each other. This type of heat sink is referred to as a passive heat sink because the direct contact of the two elements results in heat being transferred from away from the heat source (i.e., the light source 15) and to the passive heat sink (i.e., a material with a higher thermal conductivity than the heat source) without employing any active elements, such as a fan or heat pump, to remove heat from the light engine. In some embodiments, the LED light sources are attached to other materials with higher thermal conductivity than the heat source. Possible passive heat sink materials include, but are not limited to, diamond, gold, copper, silver, tungsten, silicon carbide, beryllium oxide, and aluminum nitride. Aluminum nitride is an example of a material that is thermally conductive as well as being electrically isolating. In some embodiments, it is advantageous to have a material that is both thermally conductive and electrically isolating so as to electrically isolate the light source from its power supply or other electrically connected device. In one embodiment, the heat sink can be formed from an aluminum nitride housing that is thermally connected to the light source through another high conductivity material, such as, for example, a silver-filled grease or low melting point metal-based solder, such as indium or bismuth solders. Also, a graphite pad or heat spreader, such as the eGraf heat spreader from GrafTech International Holdings of Lakewood, Ohio can be utilized to conduct and spread the heat generated by the light source into the heat sink. Advantageously, graphite has a high thermal conductivity in the plane, but across the plane (i.e., the Z axis) the thermal conductivity is not as good, but can be better than, for example, epoxies. The graphite pad can be coupled to the heat sync and used for three-dimensional thermal conductivity.

In addition to metal or thermally conductive ceramic-based printed circuit boards, other passive heat sinks 20 can be incorporated into the monolithic light engine 10. For example, slugs of copper or other highly thermally conductive materials can be placed in thermal contact with the aluminum-based printed circuit board or in contact with the light source 15. In some embodiments, the slugs of copper or other highly thermally conductive materials are shaped to include a large surface area design (e.g., fins, ridges, protrusions) which are cooled passively by convection. In addition, a passive heat sink, such as a slug of copper which is in direct contact with the light source 15, can be used in combination with a second passive heat sink that is shaped to include a large surface area (e.g., fins, ridges, protrusions).

Active heat sinks can also be used. An active heat sink utilizes a fan, other forced air system design, liquid (e.g., a piezoelectric nanopump cooling system, a liquid heat pipe), or thermoelectric cooler to remove a greater amount of heat from the heat sink, thereby cooling the heat source at a faster rate than general convection without a forced air system. Active heat sinks can be utilized in combination with passive heat sinks.

### Mechanical Connectors

The monolithic light engine 10 is packaged as a single piece unit that can be used in a multitude of different applications. The monolithic light engine 10, due to its packaging, can be removed and replaced from numerous devices (e.g., endoscopes, lighting displays, medical equipment) without the need for aligning and optically coupling the light source to the light conduit. The mechanical, rigid connection between parts allows for a robust monolithic light engine that can be handled by any user without deterioration of the light transmittance through the engine.

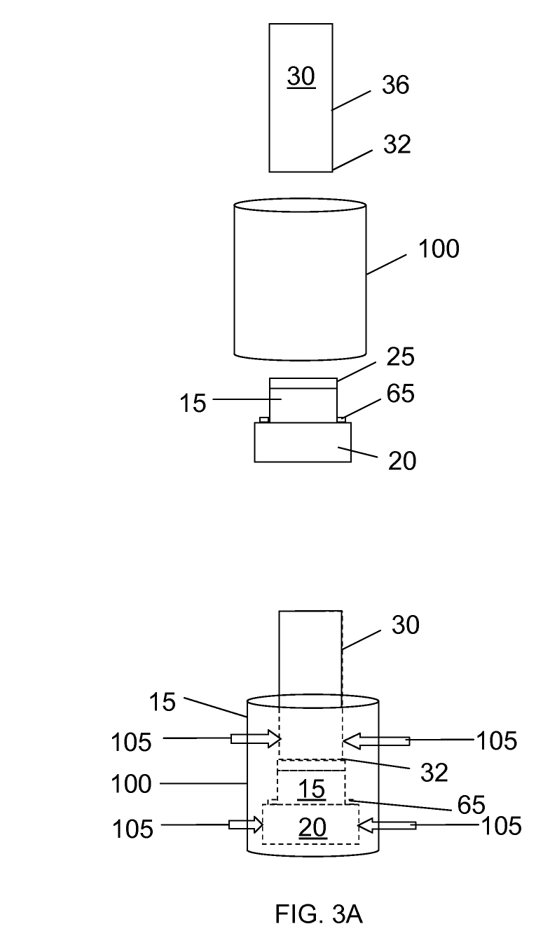

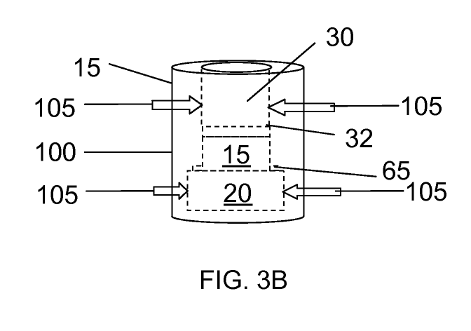

Examples of mechanical couplers include solid-phase epoxies or resins (such as, for example, silicone based adhesives, electronic potting material) and sleeve-type couplers that secure components together. For example, as shown in FIG. 3A sleeve 100 secures an exterior surface 36 of the light conduit 30 to the light source 15 by a screw-type connection 105. The wavelength converter 25 is disposed on the light receiving 32 end of the light conduit and thus, is also secured by the sleeve 100 to the light source 15. The heat sink 20 is mechanically rigidly attached to the light source 15 through the aluminum-based printed circuit board 65 to which the light source 15 (i.e., the LED) is secured. In this embodiment, the light conduit 30 extends beyond sleeve 100. In another embodiment shown in FIG. 3B, the light conduit 30 (e.g., a rod or taper) does not extend beyond the end of sleeve 100.

Another type of mechanical connection that can be used is molding. In the molding processes the components of the light engine 10 are mechanically coupled through thermoset materials. Specifically, thermoset plastics are used to rigidly attach each component together.

### Manufacturing

The monolithic light engine 10 can be made in an inexpensive, automated manner. In some embodiments, the monolithic light engine is formed by first selecting a semiconductor device that includes a substantially planar light emitting surface. As discussed above, the substantially planar light emitting surface can be an exposed LED chip surface or a substantially planar surface of a transparent window/plate or polished flat encapsulant covering the LED chip surface. In general, the semiconductor device is selected based upon the surface area of the light emitting surface and desired power requirements for the illumination device. Next, a wavelength converter material is disposed between the substantially planar light emitting surface and the light receiving end of the light conduit (e.g., deposited on the light receiving end of the light conduit, deposited proximate to the light emitting surface of the semiconductor device, disposed between the light emitting surface of the semiconductor and the light receiving end of the light conduit) selected for use with the particular semiconductor device. Finally, the light receiving end of the light conduit (e.g., with the wavelength converter disposed between the light receiving end of the light conduit and the substantially planar light emitting surface) is aligned with and attached to the substantially planar light emitting surface to form the monolithic light engine 10. The light receiving end can be attached through any mechanical process such as for example, a solid-phase epoxy, a sleeve, or a molding process.

Another method of forming the monolithic light engine 10 includes providing a semiconductor device that includes an exposed substantially planar light emitting surface. To provide the semiconductor device with exposed surface, one may remove any encapsulants, gels, liquids, and lenses covering the light emitting surface of an LED chip. Alternatively, another way to provide a semiconductor device with exposed surface is to build or to order a LED chip without any protective coverings positioned above the LED chip. Next, the wavelength converter is positioned proximate one of the substantially planar emitting surface of the light source or the light receiving end of the light guide such that the wavelength converter will be sandwiched between the light source and the light conduit upon completion of manufacturing the monolithic light engine. Then, the light receiving end of the light conduit is aligned to the exposed substantially planar light emitting surface with the wavelength converter between the light receiving end and the exposed substantially planar light emitting surface. That is, the surface area of the exposed light emitting surface of the LED chip is aligned with the surface area of the light receiving end of the light conduit so that the maximum amount of light emitted from the chip can be received by the light conduit. Finally, the light conduit is secured to the semiconductor device (LED chip) so that all three components (e.g., light conduit, wavelength converter, and LED chip) are mechanically attached together.

Another method includes providing a plurality of semiconductor devices and connecting a substantially planar light emitting surface of at least one of the plurality of semiconductor devices with a light conduit. Each substantially planar light emitting surface can be provided by building or receiving a LED chip or by removing any encapsulants, gels, liquids, and lenses covering the light emitting surface of a LED chip (e.g., removing the dome lens and gels that are included in a commercial LED). A wavelength converter is applied to the light emitting surface of each of LED chip or to the light receiving end of the light conduit. Alternatively, the LED chips may come with a wavelength converter already disposed on its light emitting surface or a separate solid wavelength converter (e.g., a disk of material including one or more phosphors and/or one or more fluorophors) can be inserted between a total emitting area (i.e., an area formed by the sum of the substantially planar light emitting surface areas of each of the plurality of semiconductor devices) and the light conduit. Next, the light receiving end of the light conduit is aligned to the substantially planar light emitting surface. That is, the surface area of the total emitting area is aligned with the surface area of the light receiving end of the light conduit so that the maximum amount of light emitted from the chip can be received by the light conduit. Finally, the light conduit is secured to the plurality of semiconductor devices (the LED chips) so that all three components (e.g., light conduit, wavelength converter, and LED chips) are secured to form a monolithic device.

Variations, modifications, and other implementations of what is described herein will occur to those of ordinary skill without departing from the spirit and the scope of the technology. Accordingly, the technology is not to be defined only by the preceding illustrative description.

1. A monolithic light engine comprising:
a heat sink;
a light emitting diode light source including a substantially planar light-emitting top surface and a back surface thermally coupled to the heat sink;
a light conduit including a light receiving end disposed proximate to the substantially planar light-emitting top surface of the light source; and
one or more mechanical connectors to rigidly couple the heat sink, the light source, and the light conduit together to form the monolithic light engine.

2. The monolithic light engine of claim 1, wherein the light emitting diode light source is battery powered.

3. The monolithic light engine of claim 1, wherein the light conduit comprises a fiber bundle.

4. The monolithic light engine of claim 1, wherein the light conduit comprises a single fiber.

5. The monolithic light engine of claim 1, wherein the light conduit comprises a rod or a taper.

6. The monolithic light engine of claim 1, wherein the light conduit comprises a liquid light guide.

7. The monolithic light engine of claim 1, wherein the light conduit is a glass light conduit.

8. The monolithic light engine of claim 1, wherein the light conduit is a plastic light conduit.

9. The monolithic light engine of claim 1, wherein the light conduit is a clad rod, a clad fiber, or a clad taper.

10. The monolithic light engine of claim 1, wherein the light conduit is a reflective-coated rod, a reflective-coated fiber, or a reflective-coated taper.

11. The illumination device of claim 1, wherein the light conduit is a taper comprising a geometric shape.

12. The monolithic light engine of claim 11, wherein the geometric shape is a circle, a square, or a hexagon.

13. The monolithic light engine of claim 1, wherein the light conduit is a taper, wherein the light receiving end comprises a first geometric shape and a light transmitting end of the light conduit comprises a second geometric shape.

14. The monolithic light engine of claim 1, wherein the light emitting diode light source includes a single light emitting diode.

15. The monolithic light engine of claim 1, wherein the light emitting diode light source includes a plurality of light emitting diodes.

16. The monolithic light engine of claim 15, wherein at least two of the plurality of light emitting diodes emit a different color.

17. The monolithic light engine of claim 1, wherein the heat sink comprises a passive heat sink.

18. The monolithic light engine of claim 1, wherein the heat sink comprises an active heat sink.

19. The monolithic light engine of claim 1, further comprising a driver to control light emission from the light emitting diode light source.

20. The monolithic light engine of claim 1, wherein the substantially planar light-emitting top surface and the light receiving end of the light conduit are selected to have substantially similar surface areas.

21. The monolithic light engine of claim 1, wherein the substantially planar light-emitting top surface of the light source is free of an encapsulant.

22. The monolithic light engine of claim 1, wherein a light transmitting plate protects the substantially planar light-emitting top surface of the light source.

23. The monolithic light engine of claim 1, further comprising a wavelength converter disposed between the substantially planar light-emitting top surface of the light source and the light receiving end of the light conduit.

24. The monolithic light engine of claim 23, wherein the wavelength converter comprises an adhesive or a gel with particles disposed therein, the particles being selected from the group consisting of phosphorescent particles, fluorescent particles, and combinations thereof.

25. The monolithic light engine of claim 24, wherein the adhesive with the particles disposed therein mechanically couples the light source to the light conduit.

26. The monolithic light engine of claim 23, wherein the wavelength converter comprises a ceramic including one or more phosphorescent materials and/or one or more fluorescent materials disposed therein.

27. The monolithic light engine of claim 26, wherein the ceramic is a solid disk disposed between the substantially planar light-emitting top surface of the light source and the light receiving end of the light conduit.

28. The monolithic light engine of claim 23, wherein the wavelength converter comprises at least one of a phosphor or a fluorophor.

29. A monolithic light engine comprising:
a heat sink;
a semiconductor light source including a light-emitting top surface and a back surface thermally coupled to the heat sink;
a wavelength converter for converting a first wavelength range emitted from the light-emitting surface to a second wavelength range; and
a light conduit including a light receiving end disposed proximate to the wavelength converter;
the heat sink, the semiconductor light source, the wavelength converter, and the light conduit being mechanically, rigidly coupled so as to form a monolithic light engine.

30. The monolithic light engine of claim 29, wherein the semiconductor light source, the wavelength converter, and the light conduit are mechanically coupled by a sleeve.

31. The monolithic light engine of claim 29, wherein the semiconductor light source, the wavelength converter, and the light conduit are mechanically coupled by a solid-phase adhesive.

32. The monolithic light engine of claim 29, wherein the heat sink comprises a passive heat sink.

33. The monolithic light engine of claim 29, wherein the heat sink comprises an active heat sink.

34. The monolithic light engine of claim 29, wherein the semiconductor light source is battery powered.

35. The monolithic light engine of claim 29, wherein the wavelength converter comprises an adhesive or a gel with particles disposed therein, the particles being selected from the group consisting of phosphorescent particles, fluorescent particles and combinations thereof.

36. The monolithic light engine of claim 35, wherein the adhesive with the particles disposed therein mechanically couples the light source to the light conduit.

37. The monolithic light engine of claim 29, wherein the wavelength converter comprises a ceramic including one or more phosphorescent materials and/or one or more fluorescent materials disposed therein.

38. The monolithic light engine of claim 37, wherein the ceramic is a solid disk disposed between the light-emitting top surface of the light source and the light receiving end of the light conduit.

39. The monolithic light engine of claim 29, wherein the wavelength converter comprises at least one of a phosphor or a fluorophor.

40. The monolithic light engine of claim 29, wherein the light conduit comprises a fiber bundle.

41. The monolithic light engine of claim 29, wherein the light conduit comprises a single fiber.

42. The monolithic light engine of claim 29, wherein the light conduit comprises a rod or a taper.

43. The monolithic light engine of claim 29, wherein the light conduit comprises a liquid light guide.

44. The monolithic light engine of claim 29, wherein the light conduit is a glass light conduit.

45. The monolithic light engine of claim 29, wherein the light conduit is a plastic light conduit.

46. The monolithic light engine of claim 29, wherein the semiconductor light source includes a single light emitting device.

47. The monolithic light engine of claim 29, wherein the semiconductor light source includes a plurality of light emitting devices.

48. The monolithic light engine of claim 29, further comprising a driver to control light emission from the semiconductor light source.

49. The monolithic light engine of claim 29, wherein the light-emitting top surface of the semiconductor light source and the light receiving end of the light conduit are selected to have substantially matching surface areas.

50. A monolithic light engine comprising:
a heat sink;
a plurality of semiconductor light sources, each source including a substantially planar light-emitting top surface and a back surface thermally coupled to the heat sink;
a light conduit including a light receiving end disposed proximate to the substantially planar light-emitting top surface of each of the plurality of semiconductor light sources; and
one or more mechanical connectors to rigidly couple the heat sink, the plurality of semiconductor light sources, and the light conduit together to form the monolithic light engine.

51. The monolithic light engine of claim 50, wherein the light conduit comprises a fiber bundle.

52. The monolithic light engine of claim 50, wherein the light conduit comprises a single fiber.

53. The monolithic light engine of claim 50, wherein the light conduit comprises a rod or a taper.

54. The monolithic light engine of claim 50, wherein the light conduit comprises a liquid light guide.

55. The monolithic light engine of claim 50, wherein the light conduit is a glass light conduit.

56. The monolithic light engine of claim 50, wherein the light conduit is a plastic light conduit.

57. The monolithic light engine of claim 50, wherein at least two of the plurality of semiconductor light sources emit a different color.

58. The monolithic light engine of claim 50, wherein the heat sink comprises a passive heat sink.

59. The monolithic light engine of claim 50, wherein the heat sink comprises an active heat sink.

60. The monolithic light engine of claim 50, further comprising a driver to control light emission from the plurality of semiconductor light sources.

61. The monolithic light engine of claim 50, wherein a total emitting area is defined by a sum of each of the substantially planar light-emitting top surfaces of the plurality of semiconductor light sources, the total emitting area and the light receiving end of the light conduit are selected to have substantially similar surface areas.

62. The monolithic light engine of claim 50, further comprising a wavelength converter disposed between the substantially planar light-emitting top surface of at least one within the plurality of semiconductor light sources and the light receiving end of the light conduit.

63. The monolithic light engine of claim 62, wherein the wavelength converter comprises an adhesive or a gel with particles disposed therein, the particles being selected from the group consisting of phosphorescent particles, fluorescent particles, and combinations thereof.

64. The monolithic light engine of claim 63, wherein the adhesive with the particles disposed therein mechanically couples the plurality of semiconductor light sources to the light conduit.

65. The monolithic light engine of claim 62, wherein the wavelength converter comprises a ceramic including one or more phosphorescent materials and/or one or more fluorescent materials disposed therein.

66. The monolithic light engine of claim 65, wherein the ceramic is a solid disk.

67. The monolithic light engine of claim 62, wherein the wavelength converter comprises at least one of a phosphor or a fluorophor.

68. A method of manufacturing an illumination device, the method comprising:
providing a semiconductor device including a substantially planar light-emitting surface;
providing a light conduit including a light receiving end and a light transmitting end;
positioning a wavelength converter between the light receiving end of the light conduit and the substantially planar light-emitting surface;
aligning the light receiving end of the light conduit to the substantially planar light-emitting surface; and
securing the light conduit to the semiconductor device to form a rigid connection.

69. The method of claim 68, wherein positioning the wavelength converter comprises depositing a film including at least one of a phosphorescent material or fluorescent material on either the light receiving end of the light conduit or on the substantially planar light-emitting surface of the semiconductor device.

70. The method of claim 68, wherein positioning the wavelength convert comprises positioning a phosphor or fluorophor layer between the semiconductor device and the light conduit.

71. The method of claim 68, wherein positioning the wavelength converter comprises positioning an element formed of a medium including one or more phosphor elements and/or one or more fluorophor elements disposed therein between the light receiving end of the light conduit and the substantially planar light-emitting surface of the semiconductor device.

72. The method of claim 68, wherein the light receiving end of the light conduit and the substantially planar light-emitting surface of the semiconductor device are secured by a solid-phase adhesive.

73. The method of claim 68, wherein the light receiving end of the light conduit and the substantially planar light-emitting surface of the semiconductor device are attached by a sleeve.

74. The method of claim 68, wherein providing the semiconductor device including the substantially planar light-emitting surface comprises providing a light emitting diode with a flat package.

75. The method of claim 68, wherein providing the semiconductor device including the substantially planar light-emitting surface comprises providing a light emitting diode including an encapsulant and planarizing the encapsulant to form the substantially planar light-emitting surface.
